(19) United States
(12) Patent Application Publication
(10) Pub. No.: US 2012/0129378 A1
(43) Pub. Date: May 24, 2012

(54) BATTERY CHARGER HAVING HANDLE THAT INCLUDES LIGHT SOURCE THAT EMITS LIGHT THROUGH APERTURE IN HANDLE CONNECTOR

(75) Inventors: JEFFREY S. KIKO, KENT, OH (US); JOSEPH MATTHEW SENK, CORTLAND, OH (US); STEVEN WILLIAM MARZO, CORTLAND, OH (US)

(73) Assignee: DELPHI TECHNOLOGIES, INC., TROY, MI (US)

(21) Appl. No.: 13/081,630

(22) Filed: Apr. 7, 2011

Related U.S. Application Data
(63) Continuation-in-part of application No. 12/950,298, filed on Nov. 19, 2010.

(51) Int. Cl. H01R 13/62; G02B 6/00; H01L 33/02; F21V 33/00

(52) U.S. Cl. 439/345; 362/253; 362/551; 362/555

(57) ABSTRACT

An electric vehicle charge coupler for both mechanically and electrically coupling and decoupling a charger to a vehicle includes a handle. The handle includes a handle connector configured for manually coupling and decoupling the handle with an inlet connector disposed on the vehicle. The handle connector further defines an aperture. The handle also includes a light source configured for activation to emit light. When the light source is activated, light emits from the light source and passes through the aperture to illuminate an area directionally out from the aperture away from the handle connector.

### RELATED APPLICATION

This application is a continuation-in-part of U.S. Application U.S. Ser. No. 12/950,298 filed 19 Nov. 2010 that is co-owned by the assignee of this application.

### TECHNICAL FIELD

This invention is directed to a battery charger for a vehicle.

### BACKGROUND OF INVENTION

It is known, referring to FIG. 1, to electrically charge a battery of an electric vehicle (2) using a battery charging system (3) that is connected to the vehicle (2). The charging system (3) includes a control box (4) connected to a vehicle coupler (5). The vehicle coupler (5) is attached to the vehicle (2) to charge the battery. The vehicle coupler includes a mechanical switch (6). When the mechanical switch (6) is closed, an electrical output changes state so that the vehicle (2) senses the presence of the vehicle coupler (5) and enables charging of the battery by the system (3). When a latch mechanism (not shown) is operated by a pulling of another trigger (not shown) or a pressing of a button (not shown), mechanical switch (6) is cycled, that is, mechanical switch (6) moves from a closed to an open position. When mechanical switch (6) is released, it returns back to its closed position. The contacts (not shown) of the mechanical switch (6) are subject to wear and may actually wear out with repeated use of the mechanical switch (6) that may lead to a decreased product life and require early undesired servicing of the mechanical switch (6). Additionally, a potentially unsafe situation may develop if the vehicle coupler (5) is disconnected from the vehicle (2) by an operator of the system (3) while the battery is simultaneously being electrically charged, otherwise known as a hot disconnect of the vehicle coupler (5). The electrical circuit as shown in prior art FIG. 1 is described in a SAE J-1772 standard for hybrid electric vehicles and electric vehicles.

Hybrid electric vehicles and electric vehicles are gaining in popularity with consumers in the marketplace. And because these vehicles may use little or no hydrocarbon fuel, they rely more heavily on the energy provided by the vehicle's battery to power a vehicle along a road. As an energy charge state of the battery of the electric vehicle decreases, the battery may need to be electrically recharged back to a fully charged energy state. As electric vehicles become more prominent, the need for battery charging systems to recharge batteries for these vehicles increases. It is desirable to provide a battery charging system that eliminates the shortcomings of the prior art as shown in FIG. 1. It is also desirable to recharge a battery with a system that provides increased safety and convenience for a user of the battery charging system. It is further desired to provide a light source associated with the handle of the charge coupler to navigate dark environments to facilitate easy charge coupler hook-up with the vehicle.

Accordingly, what is needed is a reliable battery charging system that provides increased safety and convenience for a human operator of the battery charging system.

### SUMMARY OF THE INVENTION

According to one aspect of the invention, an electric vehicle charge coupler for both mechanically and electrically coupling and decoupling a charger to a vehicle includes a handle. The handle includes a handle connector and a light source. The handle connector is configured for manually coupling and decoupling the handle with an inlet connector disposed on the vehicle. The handle connector further defines an aperture. The light source is configured for activation to emit light. When the light source is activated, light emits from the light source and passes through the aperture to illuminate an area directionally out from the aperture away from the handle connector.

In another aspect of the invention, an electric vehicle charge coupler for both mechanically and electrically coupling and decoupling a charger to said vehicle includes a handle, a non-contact switch means, a biasing means, and a light source. The handle includes a mechanical latch that securely mechanically locks the handle to the vehicle passively when the handle is manually attached to the vehicle by a human operator which creates an electrical connection between the vehicle and the charger. The handle also has an actuator movable by said operator from a deactivated state to a first and a second position activated state. The mechanical latch operates independently of the state of the actuator when the handle is being manually attached but being mechanically released by the actuator when it is moved to its second activated state. The handle further includes a handle connector that defines an aperture. The non-contact electrical switch means is associated with the actuator to break the electrical connection when the actuator is moved to the first position activated state before releasing the mechanical latch at the second activated position. The biasing means is used to automatically move said actuator back to its deactivated state when released by the operator. The light source is disposed in the handle and configured to produce light, that when activated, emits from the aperture of the handle connector to illuminate an area directionally out from the aperture away from the handle connector of the charge coupler when the charge coupler.

### BRIEF DESCRIPTION OF THE DRAWINGS

This invention will be further described with reference to the accompanying drawings in which:

FIG. 1 is a prior art electrical circuit for providing an output signal to facilitate electrical charging of a battery of a vehicle;

FIG. 2 is perspective view of an electrical charging system that includes a charging station coupled to a charge coupling handle containing a switch means and an activator according to the invention;

FIG. 3A is a partial cut-away view of the charge coupling handle of FIG. 2 with the activator in a rest position;

FIG. 3B is a partial cut-away view of the charge coupling handle of FIG. 2 with the activator in a first depress position;

FIG. 3C is a partial cut-away view of the charge coupling handle of FIG. 2 with the activator in a second depress position;

FIG. 4 is a magnified view of an extending portion of a dual-mode push button of the charge coupling handle of FIG. 3C that includes a magnet;

FIG. 5 is an electrical circuit schematic diagram of the switch means of FIG. 2 that includes a hall-effect sensor;

FIG. 6 is a block diagram of a method to mechanically and electrically couple and decouple the electrical charging system of FIG. 2;

FIGS. 7A-7C are truth tables showing operation states for elements associated with the switch means and the activator in the electrical charging system of FIG. 2;

FIG. 8 is an electrical circuit schematic diagram of the switch means that includes a reed switch according to an alternate embodiment of the invention;

FIG. 9 is a right-hand view of the charge couple handle of FIG. 3B showing light illumination out from the handle connector when the light source is turned on;

FIG. 10 is a frontal view of the handle connector of the charge couple handle of FIG. 9, showing light illumination details thereof.

FIG. 11 shows a rear view of a retainer of the handle of FIG. 3B, and details thereof; and

FIG. 12 shows a view of the light pipe of the handle of FIG. 3B, and details thereof.

### DETAILED DESCRIPTION OF THE PREFERRED EMBODIMENTS

A drivetrain of a vehicle is a group of components in the vehicle that generate power and deliver this power through the wheels of the vehicle to a road surface. A hybrid electric vehicle and an electrical vehicle each use a battery to power the drivetrain of their respective vehicles. A hybrid electrical vehicle uses a hydrocarbon fuel engine in combination with a battery disposed on the vehicle to power the drivetrain of a vehicle. An electric vehicle powers the drivetrain solely by using energy from a battery. The battery of the hybrid electric vehicle and the electric vehicle may include a plurality of batteries connected in series or parallel connection to form a single battery. As the vehicle is driven, or otherwise used by a human operator of the vehicle such as when powering the radio or windshield wipers apart from powering the drivetrain, the electrical charge on the battery may decrease such that the battery needs to be electrically recharged back to a fully charged electrical state. Recharging a battery may be accomplished using an electrical charging system that releasably connects with the vehicle. The charging assembly supplies the electrical charge to provide and fill the battery with electrical charge in a similar manner to a fuel pump that pumps hydrocarbon fuel into a fuel tank to supply an engine that operates using hydrocarbon fuel. A portion of the charging assembly may be connected with the electric vehicle and another portion of the assembly may be connected to an electrical power source to allow the charging assembly to electrically charge the battery of the vehicle.

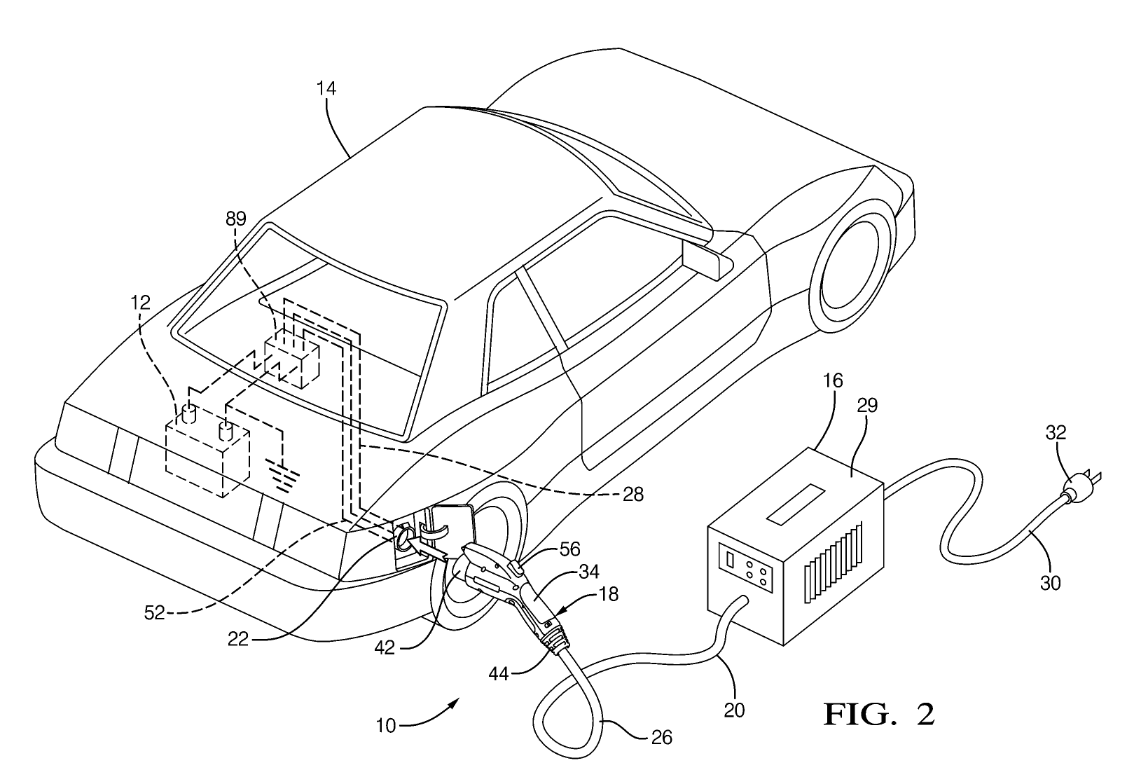

According to FIG. 2, a charging system 10 is presented to electrically charge a battery 12 of an electric vehicle 14. Alternately, the vehicle may be a hybrid electrical vehicle or any other type of motorized transportation where a battery needs electrically charged. System 10 includes a charger, or charging station 16, a charge coupling handle 18, and a cord, or cable 20 that electrically links station 16 with handle 18. System 10 is of a size suitable to package in electric vehicle 14 for storage when not in use. For example, system 10 may be stored in a trunk or an interior space of vehicle 14. Thus, system 10 may be portable with vehicle 14. System 10 may be removed from storage in vehicle 14 when battery 12 of vehicle 14 requires electrical charging of battery 12 back to a fully charged electrical state.

Handle 18, as illustrated in FIG. 2, is being coupled to a vehicle inlet receptacle, connection, or connector 22 disposed on vehicle 14. Inlet connector 22 passes electrical charge from charging system 10 to electrically charge battery 12. Inlet connection 22 is disposed at a rear exterior portion of vehicle 14 at a height suitable to allow handle 18 to be easily mated to inlet connector 22. Alternately, the vehicle inlet connection may be disposed at any interior or exterior location on the vehicle. Locating the vehicle inlet connection away from a rear portion of the electric vehicle may assist vehicle operators and other consumers to identify the vehicle as an electric vehicle in contrast to a vehicle that operates on hydrocarbon fuel that has typically and historically been fueled in the rear portion of the vehicle.

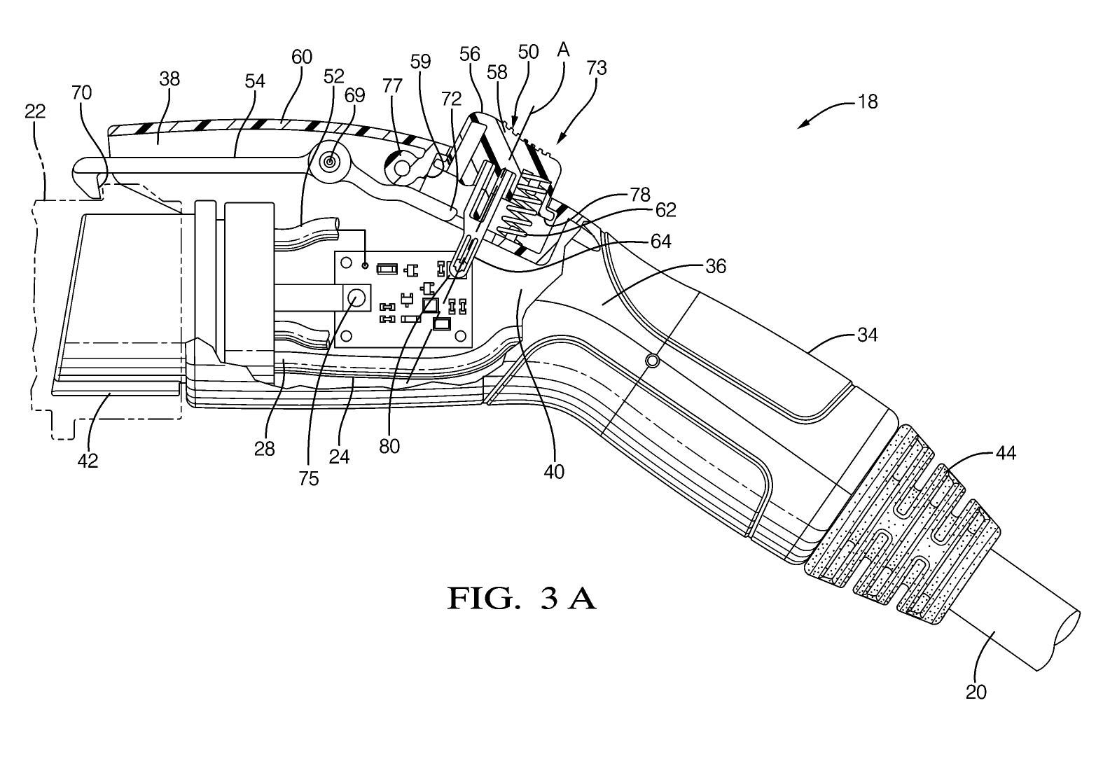

Referring to FIGS. 2-3, handle 18 contains one or more wire conductors 24 that may provide uni-directional or bi-directional flow of electrical signals between handle 18 and vehicle 14. Some of the wire conductors 24 are routed through cable 20 to charger 16. At least one of the wire conductors 28 of the one or more wire conductors 24 carries a power signal to charge battery 12 of vehicle 14. Wire conductors routed in cable 20 may be enclosed with an insulative, protective outer cover 26. For example, the insulative outer cover may be formed of a plastic sheath or formed using electrical tape wound about the wire conductors. Wire conductors 28 carrying power signals are sufficiently sized to carry a current or voltage load to effectively charge battery 12 of vehicle 14. In one embodiment, two wire conductors carrying power signals are routed through cable 20 and handle 18 into vehicle 14. Other wire conductors in cable 20 routed through handle 18 may carry electrical control signals that communicate between charging station 16 and a charge controller 89 to facilitate electrical charging of battery 12. For example, one such control signal is a pilot signal that the controller uses to handshake, and communicate with the charging station. Controller 89 manages the electrical charging of battery 12. Controller 89 receives current through the wire conductors 28 carrying power signals from handle 18 and may select to not transmit these signals to battery 12. Controller 89 may further process, or filter these power signals before supplying the filtered power signals to battery 14. Alternately, the vehicle may use other vehicle-side electrical circuit configurations and charge controller types that are effective to supply the electrical energy from the one or more power signals using the other control signals routed through the charge couple handle to the power station to electrically charge the battery of the vehicle. These other configurations are left for contemplation by the artesian.

Charging station 16 includes a housing 29. Housing 29 may be constructed of solid material such as metal or plastic. Electrical circuits that form the at least one power signals carried on wire conductors 28 in cable 20 are disposed in housing 29 and receive the voltage and/or the current from a power source (not shown). Station 16 receives power from the power source into housing 29 through an electrical cord 30. A plug end 32 of cord 30 is received by a 120 volt alternating current (AC) receptacle outlet. This voltage level is typical of what may be found when connected to an AC electrical outlet in a garage of a vehicle owner in the United States. Alternately, the charging station may have a power source with 240 volts of alternating current. Using a charging station that is powered by a power source of 240 volts AC provides more current or voltage load to charge a battery that results in charging, or recharging a battery in a less amount of time than system 10 that uses a power source of 120 volts AC. Alternately, a battery charging station may be provided that requires connection to a power source that is a voltage level other than 120 or 240 volts AC including power sources that operate on direct current (DC).

Handle 18 includes a body 34 formed from a left portion 36 and a right portion 38. Portions 36, 38 are mateable together, and when assembled together, define a space, or passage 40 through handle 18. Portions are 36, 38 are formed of a molded material such as plastic. Preferably, handle 18 is formed of a flame retardant material that may be approved and listed by Underwriters Laboratory (UL). Alternately, the body of the charge coupling handle may be integrally formed. Portions 36, 38 may be fastened together with fasteners such as screws, rivets, an adhesive, and the like. In another embodiment, seven screws attach the left and the right portion together.

Referring to FIG. 3A-3C, handle 18 includes a handle connector 42. Handle connector 42 is attached to one end of handle 18 adjacent passage 40. Handle connector 42 is suitable to mate with vehicle inlet connector 22 which receives handle connector 42. Handle connector 42 is a male connector and vehicle inlet connector 42 is a corresponding female connector 22. Alternately, the connections means may be a female connector and vehicle inlet connector be a male connector. Preferably, handle connector 42 is formed of a connector that is a SAE J-1772 approved connector. Alternately, the handle connector may be of any type connector that has a corresponding mating vehicle inlet connector that is attachable to the body of the handle. As previously described herein, charge couple handle 18 is electrically tethered to station 16 by cable 20. Wire conductors 24 are received in passage 40 at another end of handle 18 remote from handle connector 42. Wire conductors 28 carrying power signals are routed through passage 40 and received into handle connector 42. Handle connector 42 and passage 40 are suitable to route any electrical signal through wire conductors 24 in handle 18 needed to charge battery 12 of vehicle 14. A grommet 44 is attached to an end of handle 18 that receives cable 20. Grommet 44 is effective to provide strain relief for cable 20 into handle 18. Preferably, grommet 44 and handle connector 42 are secured in body 34 when portions 36, 38 are joined together.

Handle 18 mechanically and electrically couples and decouples charging station 16 with vehicle 14. Handle 18 includes a non-contact electrical switch means 48 and a mechanical latch 54 that are operatively associated with an activator 50. Switch means 48 is disposed on a printed circuit board (PCB) 81 in handle 18 and includes a wire conductor that serves as an electrical output for switch means 48, or an electrical connection 52 that communicates with handle connector 42 to vehicle 14 when handle connector 42 is connected to vehicle inlet connector 22. Mechanical latch 54 securely mechanically locks handle 18 to vehicle 14 passively when handle 18 is manually attached to vehicle 14 by a human operator between vehicle 14 and charger 16. Activator 50 in combination with switch means 48 is adapted to alter the resistance state of electrical connection 52 between a high and a low resistance state. Preferably, the high resistance state is about 480 ohms and the low resistance state is about 150 ohms. Electrical connection 52 is provided a 5 V_{DC} supply voltage through vehicle 14 when handle connector 42 of handle 18 is connected to vehicle inlet connector 22. Alternately, a different level of supply voltage may be utilized. Actuator 50 is movable by the operator from a deactivated state 73 to a first and a second position activated state 74, 76 and mechanical latch 54 operates independently of the state of actuator 50 when handle 18 is being manually attached to inlet connector 22 but being mechanically released from inlet connector 22 by actuator 50 when it is moved to its second activated state 76. Switch means 48 is associated with actuator 50 to break electrical connection 52, or put electrical connection 52 in a high resistance state, when actuator 50 is moved to first position activated state 74 before releasing mechanical latch 54 at second activated position 76. Electrical connection 52 is still physically electrically connected to inlet connector 22, but electrical connection is broken by being altered to a high resistance state. In this manner, switch means 48 combines with activator 50 to affect a resistance state of electrical connection 52 to vehicle 14 when handle 18 is connected to vehicle 14, and vehicle 14 responds back to system 10 so that system 10 electrically manages, or controls the flow of electrical current through wire conductors 28 carrying power signals in handle 18 and into vehicle 14 to allow electrical charging of battery 14 apart from independently mechanically managing a connection state of handle connector 42 in communication to vehicle inlet connector 22. Unplugging of electrical connection 52 from vehicle inlet connection 22 may not easily occur until electrical connection 52 is electrically broken, or in a high resistance state as seen by controller 89 of vehicle 14.

Referring to FIGS. 3A-3C, activator 50 is a momentary dual-activation push button 56. Momentary is defined as lasting for the moment the push-button is actually depressed. Push button 56 is disposed along a longitudinal axis A as best illustrated in FIG. 3A. Push button 56 is mounted to body 34 of handle 18 so that a head portion 58 of push-button 56 is accessible to a human operator (not shown) of handle 18. Push button 56 is fitted into an aperture 59 in handle 18. Flanges 57 surround the aperture 59 so that flanges 57 provide an interference fit for push button 56 in combination with a force supplied by biasing means, or spring 62. Spring 62 is effective to automatically move actuator 50 back to its deactivated state when released by the operator. Preferably, handle 18 is ergonomically designed so as to be grasped with a hand of the operator of system 10. One such handle is described in U.S. application Ser. No. 29/376,111 and is incorporated by reference herein. Alternately, push-button portion may be disposed anywhere along the external surface of handle 18.

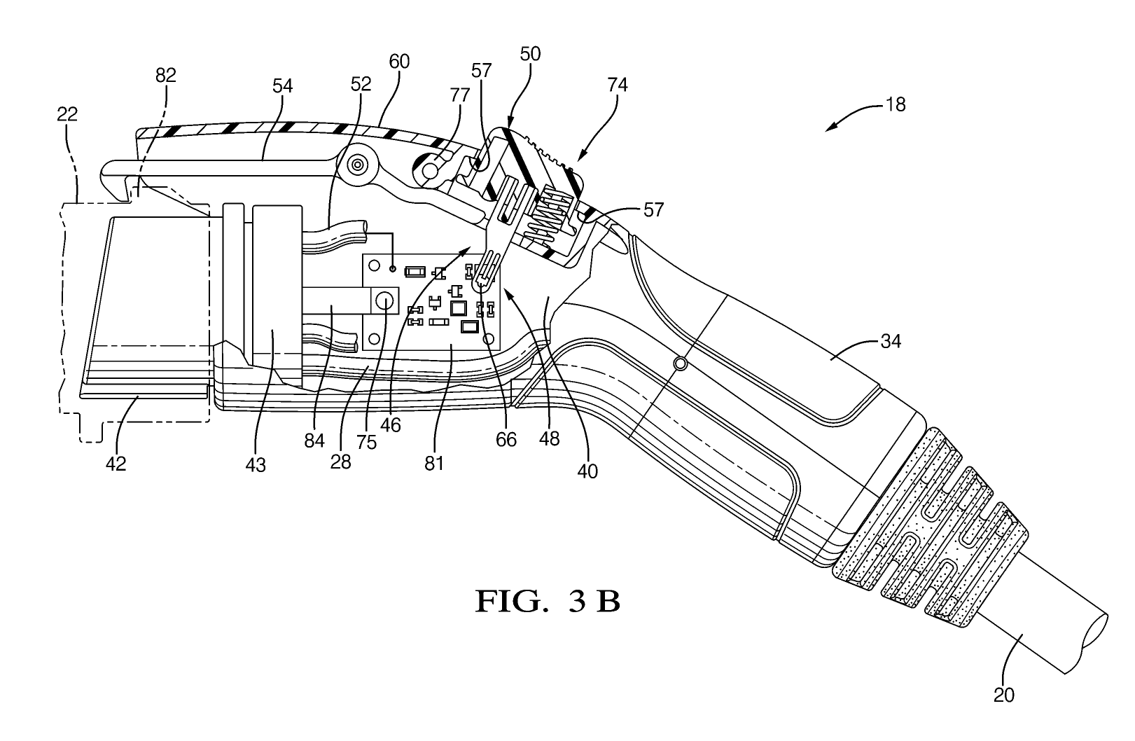

Push button 56 includes a spring 62 to bias head portion 58 and an extending portion 64 that depends axially away from head portion 58 adjacent spring 62. Push button 56 is constructed of a rigid, dielectric material such as plastic. Extending portion 64 includes a magnet 66 that is secured in extending portion 64. Preferably, magnet 66 is cylindrical. Referring to FIG. 4, magnet 66 is secured in extending portion 64 that includes a magnet retainer 67. Magnet retainer 67 receives magnet 66 at a start position 61 being installed with a tool (not shown) that allows placement of magnet 66 into start position 61 of retainer 67 so that magnet 66 is urged to slide down a ramp 63 using the tool into a locked position 65 in retainer 67. The tool used to install the magnet may be similar to a terminal pick having a pointed end having a custom form used to capture magnet 66 on its cylindrical axis and prevents magnet 66 from tipping over during installation in retainer 67. When head portion 58 is in a rest position as best illustrated in FIG. 3A, magnet 66 is proximate and overlying switch means 48. Extending portion 64 moves in a forward axial direction of axis A toward passage 40 when head portion 58 is depressed by the operator. Correspondingly, referring to FIGS. 3B and 3C, magnet 66 travels to move away from switch means 48. Extending portion 64 moves in a rearward axial direction of axis A away and outwardly from passage 40 when push-button portion is released by the operator.

The deactivation position, or rest position of push button 56, is best illustrated in FIG. 3A. Rest position 73 of push button 56 occurs when push button 56 is not pressed, or depressed by the operator of handle 18. Magnet 66 in rest position 73 of head portion 58 supplies magnetic flux to switch means 48. Spring 62 provides bias to push button 56 to position head portion 58 above external surface 60 of handle 18. A first mode of push button 56 is push button 56 being activated, or depressed in an axial first travel direction by the operator to first position activated state, or first depress position 74 as best illustrated in FIG. 3B. First depress position 74 is also a partial depress position for push button 56. First depress position 74 axially submerges a section of head portion 58 below external surface 60. Magnet 66 is moved remotely from being over switch means 48 in first depress position 74. For example, the first travel direction of head portion 58 to the first depress position 74 from rest position 73 may be a distance of 6 millimeters from rest position 71 of push button 56. A second mode of push button 56 is push button 56 being activated, or depressed in an axial second travel direction further from the first travel direction by the operator to a second position activation state, or a second depress position 76 as best illustrated in FIG. 3C. Second depress position 76 is a complete depress position of push button 56. Magnet 66 in second rest position 76 of head portion 58 is moved even more remotely from being over switch means 48 from rest position 73 and also is further remote from first depress position 74. Second depress position 76 axially substantially submerges head portion 58 below external surface 60 so that a surface of head portion 58 is about level with external surface 60. For example, a distance of the second travel direction may be 9 millimeters to second rest position 76 from rest position 71 of push button 56. Second depress position 76 has a length of travel along axis A that is greater than a length of travel of first depress position 74 where the second travel direction is greater than the first travel direction. A force provided by spring 62 moves head portion 58 back to a rest position from first depress position 74 or a second depress position 76.

Mechanical latch 54 of handle 18 includes a hook portion 70 and an engaging portion 72 opposite hook portion 70 that engages with push button 56. Latch 54 may be made of any solid material, such as metal or wood. Preferably, latch 54 is made of a dielectric material that is a plastic material. Latch 54 is disposed in passage 40 in handle 18 being secured to handle 18 with a fastener 69. Fastener 69 may be a screw or rivet, and the like. Latch 54 is also disposed in a rest position to engage a boss 77 in handle 18. Latch 54 is in a neutral, or rest position when push button 56 does not engage latch 54 as best illustrated in FIGS. 3A and 3B. Boss 77 provides a resting point for a portion of latch 54 nearest push button 56 when latch is not engaged by head portion 58. Boss 77 also provides an anchor to stabilize latch 54 when latch 54 communicates with nib 82 of vehicle inlet connector 22 when handle 18 is connected to vehicle inlet connector 22. Depression of push button 56 into second depress position 76 engages a bottom surface 78 of head portion 58 adjacent extending portion 64 against latch 54 so as to move hook portion 70 away from a shoulder 71 on vehicle inlet connector 22 so that handle connector 42 is removeable, or releaseable from vehicle inlet connector 22.

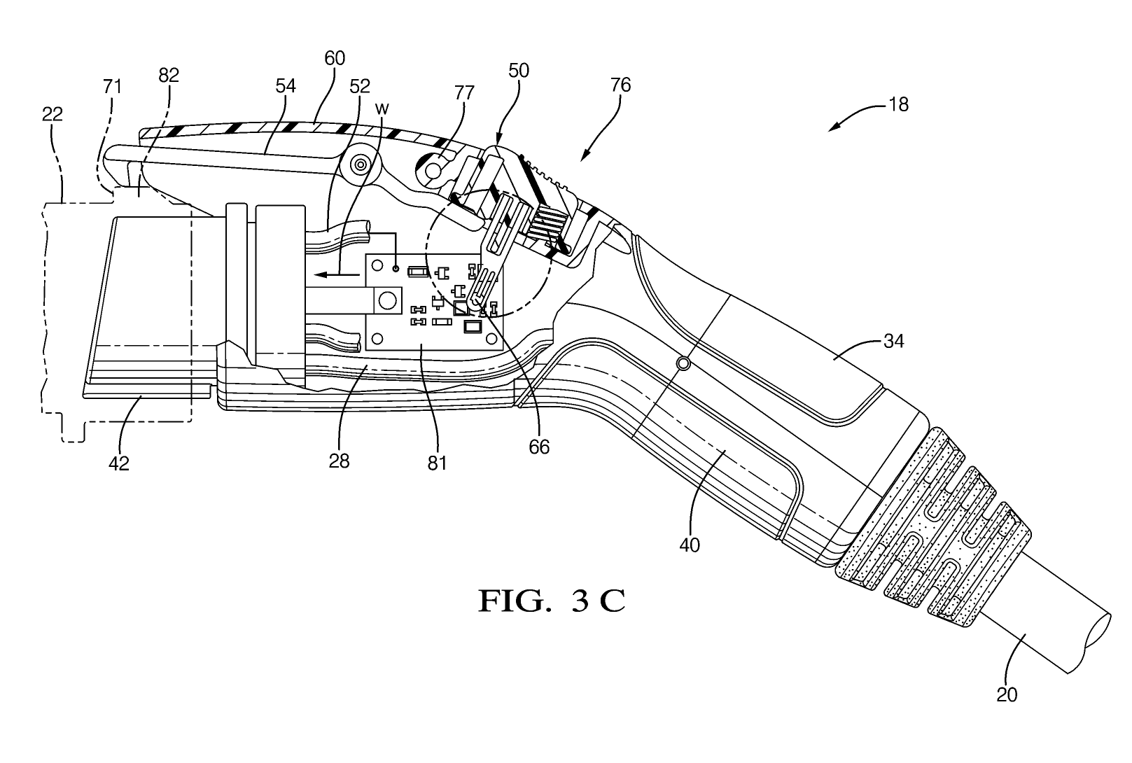

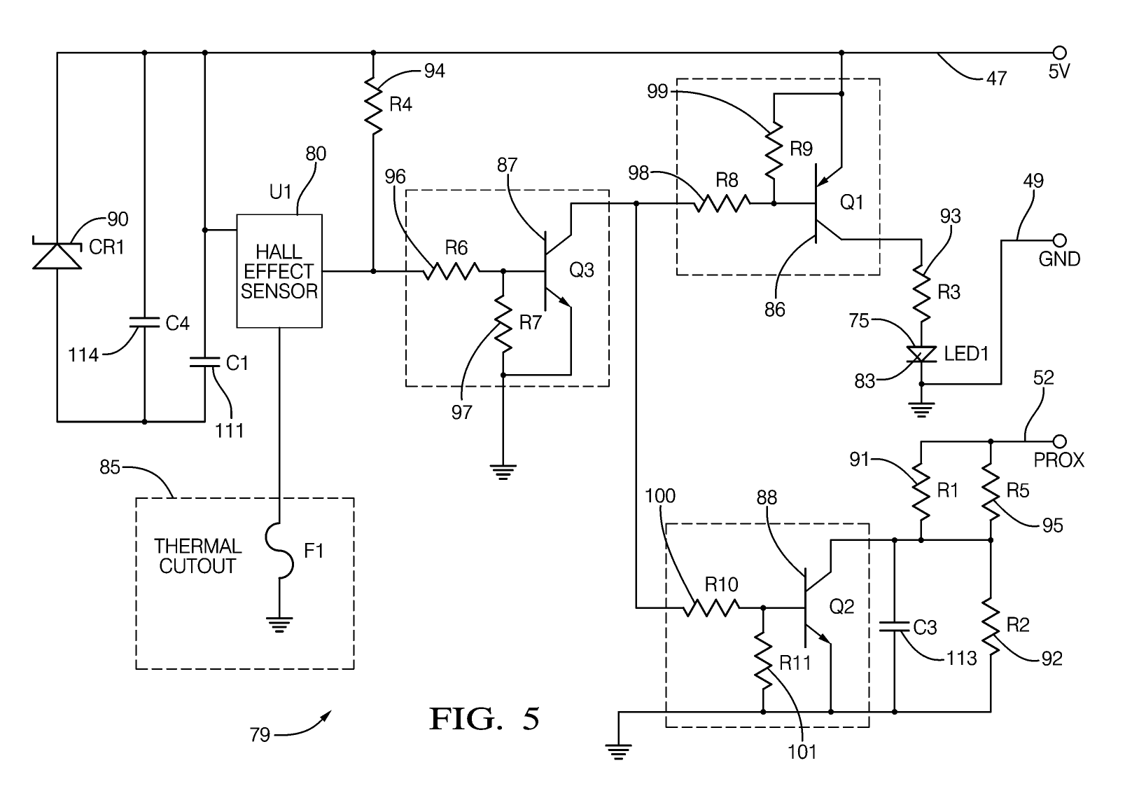

Referring to FIGS. 3-6, switch means 48 includes an electrical circuit 79 including a hall-effect sensor 80. Switch means 48 and hall-effect sensor 80 operate according to the truth table shown in FIG. 7A-&C. The primary output resistance shows the resistance states of electrical connection 52 as shown in FIGS. 5 and 7A-7C, and is the resistance as measured between electrical connection 52 and ground when looking into electrical connection 52 from vehicle 14. Hall-effect sensor 80 is disposed in an integrated circuit package that is mounted on PCB 81 along with associated other circuitry to produce electrical connection 52. The associated other circuitry on PCB 81 may include resistors, capacitors, inductors, diodes, and the like. The hall-effect sensor 80 and other associated circuitry may be attached to PCB 81 by soldering. PCB 81 is disposed in passage 40 of handle 18. PCB 81 may be secured to handle 18 in passage 40 using any suitable fastener. Preferably, circuit board 18 is secured in passage 40 of handle 18 using screws. Hall-effect sensor 80 (U1) is positioned on circuit board 81 and circuit board 81 has an orientation in passage 34 so that hall-effect sensor 80 (U1) proximate to magnet 66 on push button 56 that overlies hall-effect sensor 80 (U1) when push button 56 is in rest position 71 as best shown in FIG. 3A. When magnet 66 overlies hall-effect sensor 80 (U1) a sufficient amount of magnetic flux radiates into sensor 80 that results in proximity output, or electrical connection 52 having a first output state when handle connector 42 is mated with vehicle inlet connector 22. A suitable hall-effect sensor is commercially available from Allegro Microsystems, Incorporated under the trade designation Omnipolar Hall-Effect Digital Switches. A DC voltage power line 47 is supplied by charging station 16 to PCB 81 of handle 18 to operate circuit 79 and supply voltage to power hall-effect sensor 80 and a light source, or lamp 75. Lamp 75 may need to operate even if handle 18 is not connected to vehicle inlet connection 22. DC voltage power line 47 may be a 5 V_{DC} electrical signal. Alternately, the DC voltage power line may have a voltage level different from 5 V_{DC}. Circuit 79 is grounded to charging station 16 through ground 49. Ground 49 may be connected with the battery charging system and the battery charging system ground may be an earth ground. Alternately, the grounds between the charging system and the vehicle may have a common ground being the chassis ground of the vehicle. The chassis ground may be earth ground.

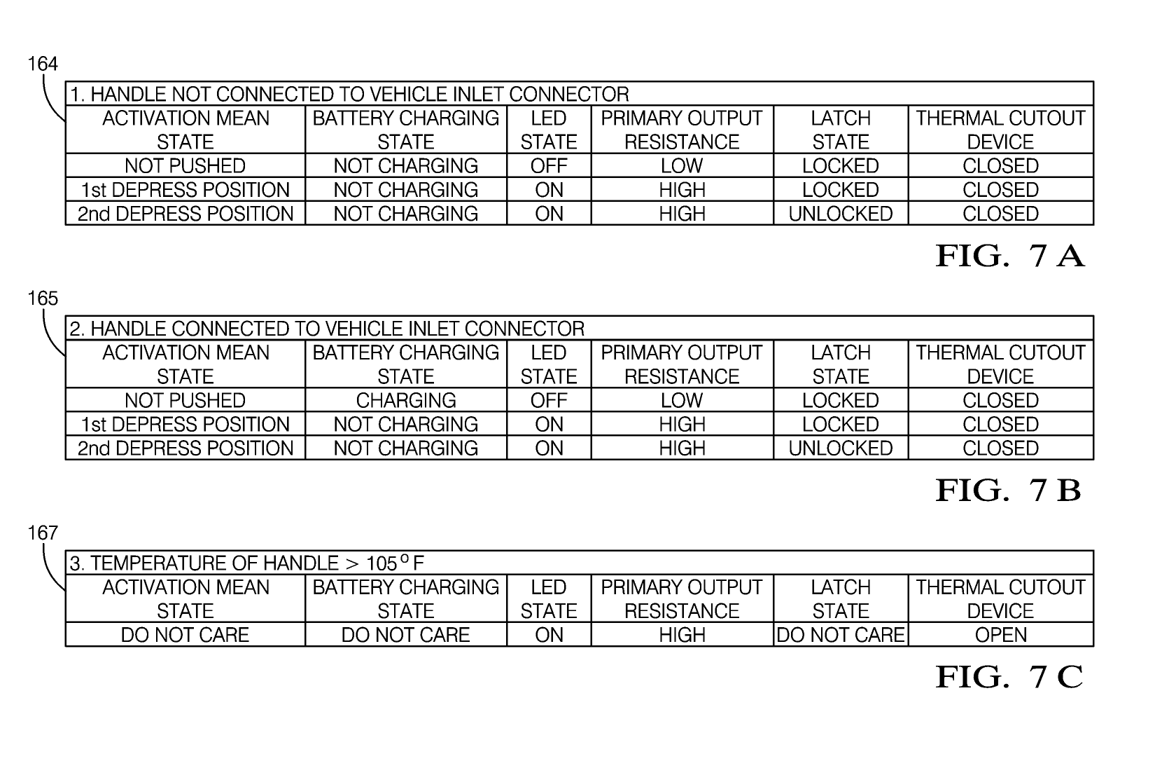

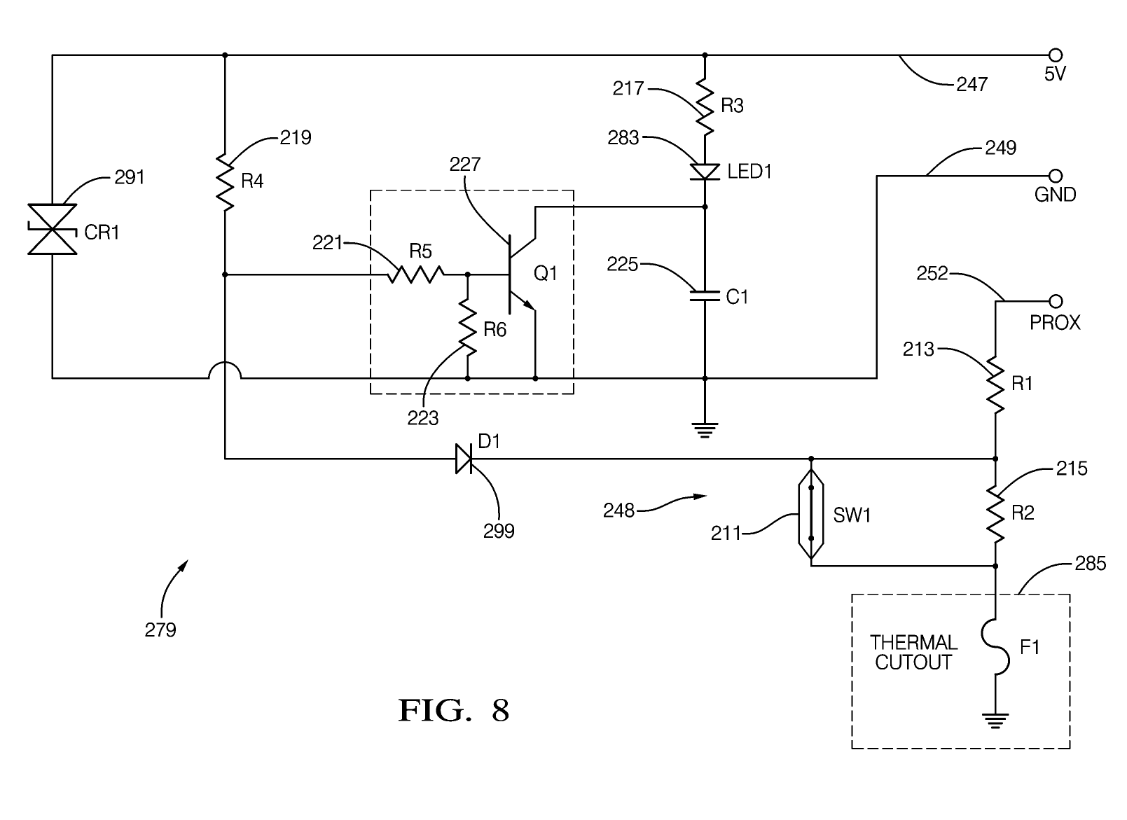

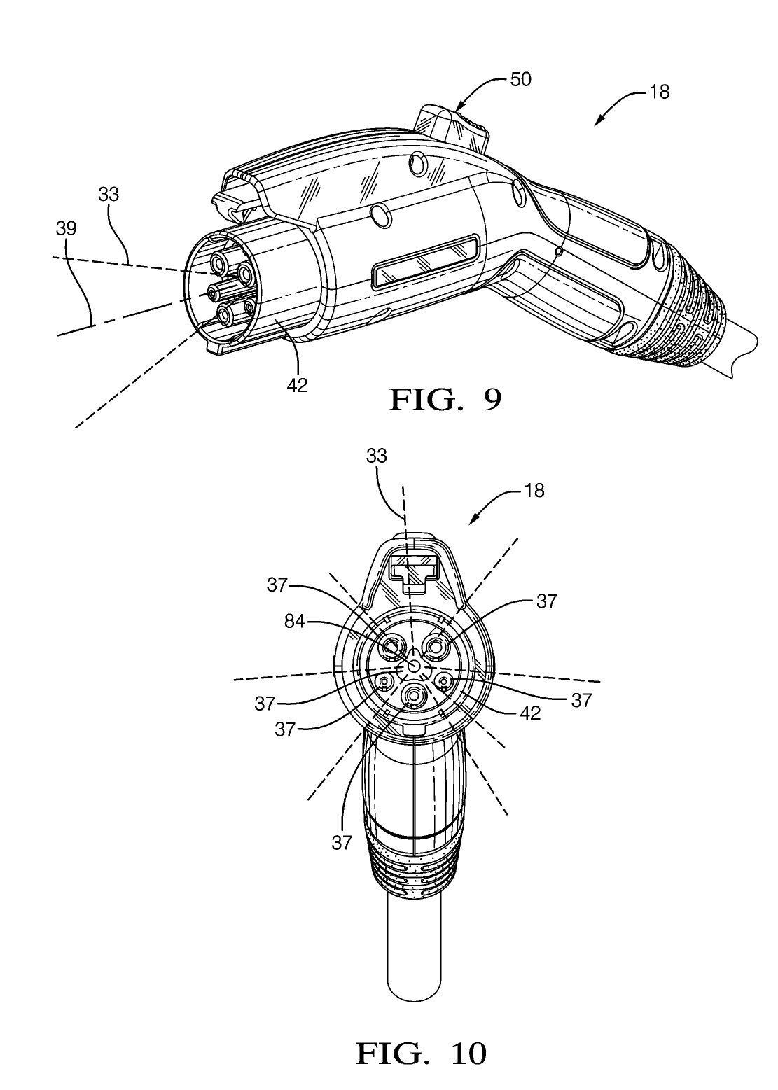

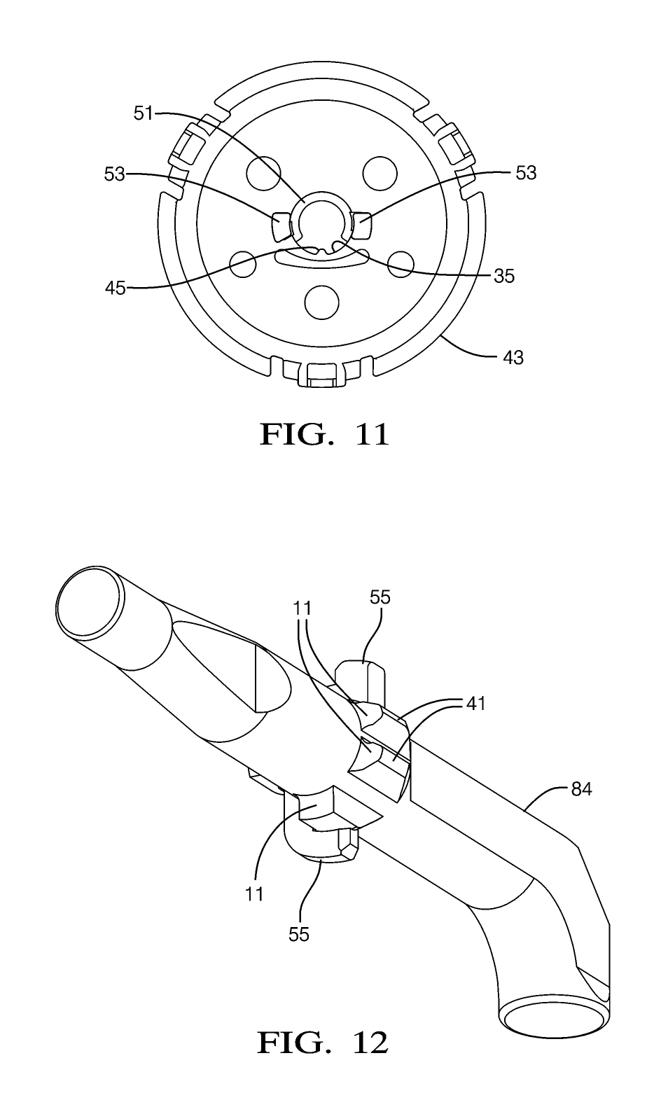

Referring to FIGS. 9-10, when lamp 75 is turned on, or activated, lamp 75 is emits light that passes through passage 40 and out from an aperture 35 defined in handle connecter 42 of handle 18 to provide light illumination 33. Light illumination 33 is provided in an area directionally out from aperture 35 away from handle connector 42 that is quite useful to locate vehicle inlet connector 22 when the vehicle is disposed in a dark environment. More specifically, the light passing through aperture 35 has a direct beam component 39 that provides a generally increased intensity focus of light within the area of light illumination 33 that is advantageous especially in a dark environment to more directly guide the mating of handle connector 42 to vehicle inlet connector 22. The direct beam component 39 may be directed right at vehicle inlet connector 22 and handle connector 42 then movingly guided along the path of direct beam component 39 to guidingly mate, or couple with the targeted vehicle inlet connector 22. This provides enhanced ease of use for a human operator of handle 18. Lamp 75 is activated when activator 50 is disposed in at least one of first depress position 74 or second depress position 76.

Electrical connections 52 include a plurality of electrically-conductive terminals (not shown) that interface with vehicle inlet connector 22. Terminals are made of a metal material such as brass or copper alloy and are encased with connector terminals 37 of handle connector 42. Aperture 35 is generally disposed co-axially disposed in handle connector 42 where connector terminals 37 surround, or encircle aperture 35.

Light pipe 84 is disposed intermediate aperture 35 and light source 75 in passage 40 of handle 18, as best illustrated in FIG. 3B. Light pipe 84 is insertable in aperture 35 and mechanically secured to handle connector 42 so that light emitted from light source 75 is focusingly transmitted through light pipe 84 and out through the aperture 35. Lamp 75 is a light emitting diode 83 (LED1). Alternately, lamp 75 may be any element or device that emits light such as an incandescent bulb. A light pipe 84 focuses and transmits the light provided by diode 83 (LED1) thru passage 40 and out aperture 35 in handle connector 42 in handle 18. Light pipe 84 is constructed so that light that enters light pipe 84 from diode 83 (LED1) emits from light pipe 84 out aperture 35 having a white color. Alternately, the light source and the light pipe may be chosen to provide light having another color other than white light. Alternately, the light source may not be employed in the handle.

Light pipe 84 is constructed to be insertable in aperture 35 in an insertion direction w to abut a front surface of handle connector 42 on the same side of handle connector 42 as connector terminals 37. More particularly, handle connector 42 includes a retainer 43 attached to handle connector 42 that defines aperture 35. Retainer 43 includes a flexible lock 45 and light pipe 84 includes at least one locking rib 41. Locking ribs 41 extend from an external surface of light pipe 84 and receivingly engage flexible lock 45 when light pipe is assembled to a forward stop 51 in aperture 35 of retainer 43. During assembly of light pipe 84 to retainer 43, pipe 84 is inserted through aperture 35 until forward surfaces 11 of locking ribs 41 of light pipe 84 bottom out on a surface of forward stop 51 in aperture 35 of retainer 43. Light pipe 84 is secured to connector handle 42 with opposing tabs 55 disposed along an external surface above and below light pipe 84 that are attachable to retainer towers 53 and flexible lock 45 of a retainer 43 of connector handle 42. Locking ribs 41 are configured to operatively assist to secure light pipe 84 to retainer 43 of handle connector 42 such that when light pipe 84 is mechanically secured to retainer 43, locking ribs 41 do not interfere with the transmission of light through light pipe 84 that is subsequently emitted out through aperture 35. Once forward surfaces 11 of locking ribs 41 of light pipe 84 bottom out on a surface of forward stop 51 in aperture 35 of retainer 43, light pipe 84 is further secured in retainer 43 and aligned with diode 83 (LED1) with a quarter rotational turn of light pipe 84 about insertion direction w. The quarter rotational turn is then facilitated to pipe 84 so that the laterally opposing tabs 55 are secured by retainer towers 53 and locking ribs 41 secured with flexible lock 45. With alignment of pipe 84 to diode 83 (LED1), pipe 84 is ready to capture light from diode 83 (LED 1) when diode 83 (LED1) is activated.

A thermal cutout device 85 (F1) is disposed on PCB 81 in handle 18 and is suitable to sense if an over-temperature condition exists at least in handle 18 which encompasses an environment about thermal device 85. This environment may further extend out to include vehicle inlet connection 22 when charge couple handle 18 is connected with vehicle inlet connection 22. For example, an over-temperature condition may be experienced if a hot thermal failure develops in the handle when the handle is connected to vehicle inlet connector 22. If thermal device 85 (F1) is activated due to an over-temperature event, device 85 determines the output state of electrical connection 52 as shown in truth table 167 in FIG. 7C. Device 85 cuts out, or opens to determine the primary output resistance of electrical connection 52 to a high resistance state so controller 89 of vehicle 14 stops transmission of power signals 28 through handle 18. Advantageously, this feature may prevent handle 18 from becoming undesirably hot, emit a burning odor, or becoming deformed due to the over-temperature condition. Preferably, device 85 is tripped, or activated to be cut-out when a temperature sensed by thermal device 85 exceeds 105 degrees Celsius (° C.)±5° C. A suitable thermal shutdown device is commercially available from Cantherm under the trade designation Thermal Cutouts. If the over-temperature condition is induced due to a vehicle side thermal failure, thermal device 85 is resettable to allow handle 18 of station 10 to recover from the vehicle-induced thermal failure. For example, device 85 is recoverable when the temperature of device 85 is sensed to be about 70° C., which is about 35° C. below the 105° C. threshold. Preferably, thermal device 85 is strategically positioned in handle 18 intermediate two power signals 28 disposed within handle 18. Thermal device 85 is configured to be in physical contact with the wire insulation of both wire conductors 28 carrying power signals to achieve the best response time in sensing an over-temperature condition permeating through the wire conductors 28 carrying power signals. Alternately, the thermal cutout device may not be employed in the handle.

When handle connector 42 of handle 18 is not connected with vehicle inlet connector 22, charging of battery 12 of vehicle 14 will not occur. Referring to FIG. 7A-C, reference numeral 164 shows various states of operation associated with switch means 48 in combination with activator 50 when handle 18 is not connected to vehicle inlet connector 22. If head portion 58 of push button 56 is depressed by the operator to at least first depress position 74, LED 83 emits light through the aperture in handle 18 to provide light in a darkened environment to locate vehicle inlet connection 22. LED 83 will stay on when head portion 58 is depressed past first depress position 74 and also stays on when in second depress position 76. The other operation states operate as shown in reference numeral 164, but are irrelevant as handle 18 is not connected to vehicle inlet connection 22.

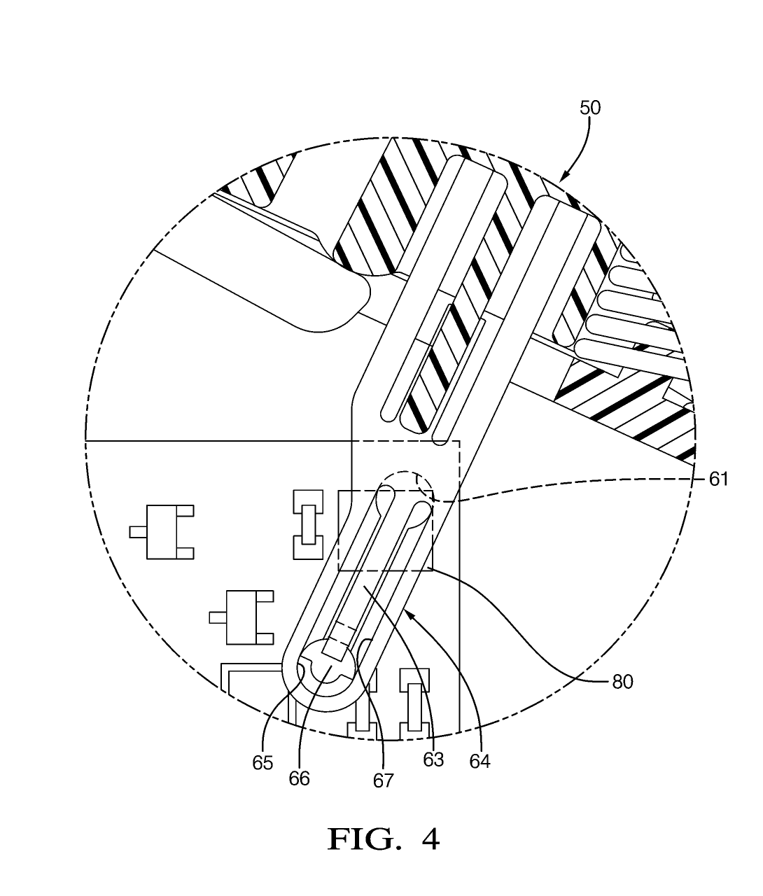

Referring to FIGS. 3A-3C, 7A-7C, when station 16 is connected to the 120 V_{AC} power source, and handle connector 42 is connected to vehicle inlet connector 22, and head portion 58 is in rest position 71, charging of battery 12 of vehicle 14 may commence. Referring to FIGS. 6 and 7, method 150 is presented to control electrical charging of battery 12 and reference numeral 165 shows the various states associated with switch means 48 in combination with activator 50 when handle 18 is being mated to vehicle inlet connection 22. One step 152 in method 100 is to connect handle 18 to vehicle inlet connector 22 that passively connects mechanical latch 54 with vehicle inlet connector 22. The operator of system 10 grasps handle 18 and moves handle 18 towards inlet connector 22. When inlet connector 22 is located by the operator, handle connector 42 of handle 18 is mated to vehicle inlet connector 22. Hook portion 70 of mechanical latch 54 rides over nib 82 with insertion of handle connector 42 to engage shoulder 71 of inlet connector 22. Nib 82 includes a ramp portion that transitions into the outer surface of inlet connector 22. Engagement of hook portion 70 against shoulder 71 prevents inadvertent removal of handle 18 from inlet connector 22. This secures latch 54 to vehicle inlet connection 22 in a locked state. When handle 18 is mated to vehicle inlet connection 22 the supply voltage for electrical connection 52 is provided by vehicle 14. Terminals (not shown) in handle connector 42 are in electrical communication with corresponding terminals (not shown) in vehicle inlet connection 22 before hook portion 70 engages shoulder 71. For example, the hook portion may engage the shoulder after about 1 millimeter of travel past where the terminals of the handle connector and the terminals of the vehicle inlet connectors are connected. When handle connector 42 is electrically connected with vehicle inlet connection 22, wire conductors 28 carrying power signals are provided for transmission through handle 18 to electrically charge battery 12 on vehicle 14.

When handle 18 is mated to inlet connection 22 and head portion 58 is in rest position 71 and push button 54 is not depressed, electrical connection 52 is at a low resistance state looking into electrical connection 52 as seen by vehicle 14. Magnet 66 is overlying hall-effect sensor 80 supplying magnetic flux to hall-effect sensor 80 to ensure circuit 79 keeps electrical connection 52 in a low resistance state. When controller 89 of vehicle 14 senses the low resistance state of electrical connection 52, controller 89 communicates with charging system 10 to transmit at least one power signal on wire conductor 28 through handle 18 to charge battery 12 in vehicle 14.

When the operator desires to disconnect system 10 by uncoupling handle 18 from vehicle inlet connector 22, the operator depresses head portion 58 of push button 56 to second depress position 76 which is step 162 in method 150. This may occur, for example, when battery 14 has been completely electrically charged and has a full electrical charge. When battery 12 has a full electrical charge, system 10 is no longer needed. Second depress position 76 cannot be attained until dual-mode push button is induced, or moved initially through first depress position 74. The depression of head portion 58 to first depress position 74 is defined as a partial depress of head portion 58, as captured in step 160 of method 150. The depression of head portion 58 to second depress position 76 is defined as a complete depress of head portion 58. When head portion 58 is induced to first depress position 74, magnet 66 travels away from hall-effect sensor 80. Magnetic flux no longer influences hall-effect sensor 80 and the performance of circuit 79 operates to change the electrical state of electrical connection 52 to a high resistance state. Controller 89 in vehicle 14 senses the high resistance state of electrical connection 52 and configures system 12 to stop transmission of one or more power signals 28 through handle 18. When wire conductors 28 carrying power signals are not transmitted, battery 12 is not being electrically charged. In first depress position 74, latch 54 is still in the locked state and handle 18 is not releasable from vehicle inlet connection 22. When head portion 58 is depressed to second depress position 76, surface 78 of head portion 58 engages latch 54 to move latch 54 to a position that is outwardly away from shoulder 71 of vehicle inlet connector 22 so that hook portion 70 of latch 78 is clear of shoulder 71. When latch 54 is clear of shoulder 71, handle connector 42 of handle 18 may be removeably uncoupled from vehicle inlet connection 22. Thus, the transmission of power signals on wire conductors 28, which is defined as a hot signal, is stopped before handle connector 42 of handle 18 is removeable from vehicle inlet connector 22 to prevent handle 18 from being removed while battery 12 is still being charged. This feature enhances the safety to the operator that uses charging system 10. If the battery continued to be electrically charged while the handle is also being disconnected from the vehicle inlet connection, undesired electrical arcing across the terminals of the handle connector and vehicle inlet connection may result which may degrade these connections. Arcing may degrade these connections by causing material of terminals in these connections to break away resulting in high impedance in the connection which lowers the effective electrical conductivity in the connection.

Referring to FIGS. 5 and 7A-7C, and turning our attention to the operation of circuit 79, switch means 48 includes hall-effect sensor 80 (U1) that has four modes of circuit operation when handle connector 42 is mated to vehicle inlet connector 22. A first operation state occurs when head portion 58 of push button 56 is in rest position 71, or not depressed and thermal device 85 (F1) does not sense an over-temperature condition in handle 18. A second operation state occurs when head portion 58 is depressed to first depress position 74 and thermal device 85 (F1) does not sense an over-temperature condition. A third operation state occurs when head portion 58 is depressed to second depress condition 76. A forth operation mode occurs when thermal device 85 (F1) senses an over-temperature condition in handle 18.

Referring to FIG. 5, thermal device 85 (F1) is electrically connected to hall-effect sensor 80 (U1) and diode 83 (LED1) is in electrical communication with hall-effect sensor 80 (U1) through electronic transistor devices 86 (Q1), 87 (Q3). Transistor 86 (Q1) provides the necessary current to operate diode 83 (LED1) when transistor 86 (Q1) is turned on. Transistor 87 (Q3) provides a buffer between the output of hall-effect sensor 80 (U1) and transistor driver 87 (Q3). Electrical switching device, or transistor device 88 (Q2) is in electrical communication with hall-effect sensor 80 (U1) and with inlet connector 22 through PROX line, or electrical connection 52, to controller 89 in vehicle 14. Voltage suppressor 90 (TVS 1) is used to protect hall-effect sensor 80 (U1) from transient voltages that could be coupled onto the 5 V_{AC} supply line by limiting the maximum voltage that may be applied to hall-effect sensor 80 (U1). Resistors 91-101 are used to provide proper biasing levels for respective transistors 86-88 (Q1-Q3). Capacitors 111, 113-114 provide additional electrical filtering for electrical signals in circuit 79.

### First Circuit Operation State—Hall-Effect Sensor

As previously described herein, the first state of operation using hall-effect sensor 80 (U1) is where thermal device 85 (F1) does not sense an over-temperature condition and head portion 58 of push button 56 is in rest position 71. Referring to FIGS. 3A, 5, and 6, the first operation state includes electrical connection 52 (prox) being in a low resistive state. The low resistance state is attained when head portion 58 is in the rest position regardless of whether handle 18 is connected or not connected to vehicle inlet connection 22. Referring now to FIG. 3A, head portion 58 is not depressed so that magnet 66 is centered over hall-effect sensor 80 (U1). A threshold of magnet flux supplied to sensor 80 (U1) ensures an output of hall-effect sensor 80 (U1) electrically connecting with transistor 87 (Q3) is at a low resistance state. This low resistance state is output to transistor 86 (Q1) turns transistor 87 (Q1) off which subsequently turns off transistor 87 (Q3). With transistors 86 (Q1), 87 (Q3) turned off, each transistor device has an open collector output. With transistor 87 (Q3) being turned off, diode 83 (LED1) is also turned off so no light emits from diode 83 (LED1) through aperture of handle connector 42 and out of handle 18. With transistors 86 (Q1) and 87 (Q3) being turned off, and the collector of transistor 87 (Q3) being pulled near the 5V supply, transistor 88 (Q2) is turned on and electrical connection 52 is at a low voltage level or ground voltage potential.

### Second Circuit Operation State—Hall-effect Sensor

Referring to FIG. 3B and step 160 of method 150 in FIG. 6, the second operation state is attained when the operator activates, or depresses head portion 58 of push button 56 to a partially induced position, or first depress position 74. Thermal device 85 (F1) does not sense an over-temperature condition in handle 18 and electrical connection 52 is in a high resistive state. When push button 56 is depressed to first depress position 74, magnet 66 moves away from hall-effect sensor 80 (U1). Magnetic flux decreases such that the output of hall-effect sensor 80 (U1) is electrically changed to be an open circuit having high impedance. With the output of hall-effect sensor 80 (U1) being an open circuit, the voltage on transistor 87 (Q3) is pulled up near the 5 V_{DC} supply voltage turning transistor 87 (Q3) on, which effectively puts the collector of transistor 87 (Q3) at ground voltage potential. With transistor 87 (Q3) turned on, transistor 87 (Q3 becomes saturated allowing the collector of transistor 87 (Q3) to be pulled near the 5V supply voltage and transistor 86 (Q1) to be turned on allowing current flow through transistor 87 (Q3) to supply current to diode 83 (LED1) so that diode 83 (LED1) turns on. Light from diode 83 (LED1) is provided through lightpipe 84 and emits out from aperture of handle 18 illuminating an area beyond the aperture of handle 18 in a dark environment to assist the operator to locate vehicle connector 22. With transistors 86 (Q1) and 87 (Q3) being turned on, and the collector of transistor 87 (Q3) being pulled near the ground voltage potential, transistor 88 (Q2) is turned off and electrical connection 52 attains a high resistance state. The high resistance state is sensed by controller 89 in vehicle 14 and controller 89 electrically communicates with station 16 through other wire conductors 24 in handle 18 to transmit power signal on wire conductor 28 to charge battery 12 of vehicle 14.

### Third Circuit Operation State—Hall-effect Sensor

In a third state of operation of hall-effect sensor U1, head portion 58 is completely depressed, or depressed into second depress position 76. The high resistance state of electrical connection 52 is maintained as magnet 66 is even further removed from hall-effect sensor 80. In second depress position 76, head portion 58 engages latch 54. The cantilever action of the latch 54 causes hook portion 70 of latch 54 to move out and away from inlet connection 22 and allow handle connector 42 to be removed from inlet connection 22. As previously discussed herein, when push button 56 is depressed to at least first depress position 74, light emitting diode 83 (LED1) is activated. Diode 83 (LED1) also stays on if head portion 58 is disposed between first depress position 74 and second position 76 or if push button 56 is in second depress position 76.

### Fourth Circuit Operation State—Hall-Effect Sensor

In a fourth state of operation thermal device 85 (F1) senses on over-temperature condition in handle 18 and configures electrical connection 52 in a high resistive state. Thermal device 85 cuts out, or breaks when the temperature in handle exceeds 105 degrees Celsius. The other elements associated with switch means 48 and activator 50 are ‘don't care’ or irrelevant as illustrated by reference numeral 167 in FIG. 7C. Thermal device 85 ensures electrical connection 52 is configured to the high resistive state that ensures transmission of power signals on wire conductors 28 are stopped. This provides enhances safety to the operator of handle 18 of system 10. If the power signals transmit electrical energy when an over-temperature condition occurs device 85 essentially mitigates overheating that may occur in handle 18 if the contact resistance between the power terminals attached to wire conductors 28 carrying of power signals of handle connector 42 and vehicle inlet connection 22 increased for any reason, such as if undesired dirt or debris gets trapped between this terminals. If the power signals are not shut down, a constant current would continue to be supplied through this increased resistance that eventually results in undesired deformation of the terminal contacts of wire conductors 28 carrying power signals. If the deformation is severe, electrical conductivity may not occur.

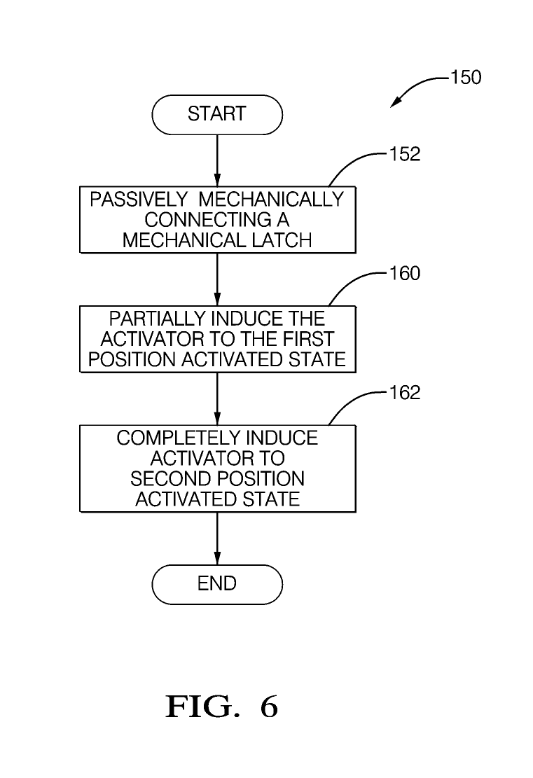

Referring to FIG. 8, in an alternate embodiment of the invention where similar elements have reference numerals differing by 200, a non-contact electrical switch means 248 is disposed in an electrical circuit 279. Switch means 248 is a reed switch 211 (SW1) used in combination with an activator (not shown) that manages, or controls an electrical connection 252 independently from unsecuring the handle connector (not shown) from the vehicle inlet connection (not shown). Reed switch 211 (SW1) is a magnetically activated switch. The activator is a dual-mode push button similar to the dual-mode push button of the embodiment of FIGS. 2-7, and is previously described herein. The truth table for the embodiment of FIG. 8 may be similar to that of the embodiment of FIGS. 2-7, as previously described herein, and as shown in FIGS. 7A-7C. The reed switch interacts with the magnet associated with the dual-mode push button, similar to the embodiment of FIGS. 2-7. The alternate embodiment of FIG. 8 is also similar to the embodiment of FIG. 5 that includes the hall-effect sensor in that there are four modes of operation when the handle connector is mated to vehicle inlet connector. A first operation state occurs when reed switch 211 (SW1) is in a normally closed position as illustrated in FIG. 8. When the dual-mode pushbutton of the embodiment of FIGS. 2-7 is not depressed by the operator of the charging system the dual-mode pushbutton is in a rest position and reed switch 211 (SW1) is in a normally closed position as illustrated in FIG. 8. Thermal device 285 (F1) does not sense an over-temperature condition in the charge coupling handle. A second operation state occurs when the dual-mode pushbutton is depressed to first depress position (not shown) and thermal device 285 (F1) does not sense an over-temperature condition in the charge coupling handle. A third state of operation is when the dual-mode push button is depressed into the second depress position (not shown) and thermal device 285 (F1) does not sense an over-temperature condition in the charge coupling handle. A fourth operation mode occurs when thermal device 285 (F1) does sense an over-temperature condition in the charge coupling handle. Voltage suppressor 291 (TVS 1) is used to limit the supply voltage supplied from vehicle 14 to 5V. Resistors 213, 215, 217, 219, 221, 226 are used to provide proper biasing levels for transistor 287 (Q1), 283 (LED1) and electrical connection 252. Capacitor 225 provides additional filtering for signals in circuit 279. A DC voltage supply line 247 assists to supply operating voltage for circuit 279. Power line 247 may supply voltage for diode 283 (LED1) disposed on a printed circuit board (not shown) in the charge coupling handle. Power line 247 is supplied from the charging station (not shown). Circuit 279 is grounded to charging station through ground 249. The ground 249 is similar to ground 49 in the embodiment of FIGS. 2-7.

### First State of Operation—Reed Switch

The first state of operation uses reed switch 211 (SW1) where thermal device 285 (F1) does not sense an over-temperature condition. Referring again to FIG. 8, the first operation state includes electrical connection 252 (prox) being in a low resistive state with thermal device 285 (F1) being closed. Preferably, the low resistance state between electrical connection 252 and ground voltage potential is about 150 ohms. The head portion (not shown) of the dual-mode push button (not shown) is not depressed so that a sufficient amount of magnet flux is applied to reed switch 211 (SW1) from the magnet (not shown) to keep reed switch 211 (SW1) in a normally closed position, as illustrated in FIG. 8, keeping electrical connection 252 at a low impedance state. As shown in FIG. 8, electrical connection 252 is at about ground voltage potential. Transistor 227 (Q1) is turned off with the base of transistor 227 (Q1) being at a voltage above the voltage drop across diode 299 (D1). With transistor 227 (Q1) off the current flow through diode 283 (LED1) is minimal and diode 283 (LED1) is turned off. With diode 283 (LED1) turned off, no light is provided through the charge couple handle.

### Second State of Operation—Reed Switch

Thermal device 285 (F1) does not sense an over-temperature condition in the charge coupling handle and electrical connection 252 is in a high resistive state. Preferably, the high resistance state between electrical connection 252 and ground voltage potential may be a resistance of about 480 ohms. When the head portion of the dual-mode push button is depressed to first depress position, the magnet moves away from reed switch 211 so that the magnetic flux applied to reed switch 211 decreases. Reed switch 211 now switches to an open position allowing current to flow through resistors 213 (R1), 215 (R2). The voltage increases at the base of transistor 227 (Q1) sufficiently to turn transistor 227 (Q1) on. Turning 227 (Q1) on, allows current to flow through resistor 217 (R3) and diode 283 (LED1) to turn on diode 283 (LED1) and provide light emitting through the charge couple handle. Electrical connection 252 transitions to a high resistance state.

### Third State of Operation—Reed Switch

In a third state of operation, the dual-mode push button is depressed to a second depress position. In the second depress position, the dual-mode push button engages the latch similar to the embodiment of FIGS. 2-7.

### Forth State of Operation—Reed Switch

A fourth state of operation, thermal device 285 (F1) does sense an over-temperature condition in the charge coupling handle. When device 285 (F1) senses an over-temperature condition, device 285 (F1) breaks, or cuts out. When device 285 (F1) cuts out, electrical connection 252 is configured to a high impedance state. Preferably, the high impedance state is a high resistance state between electrical connection 252 and ground voltage potential. The resistance in the high resistance state may be about 1 Megaohm.

If electrical circuit 279 is employed without using diode 283 (LED1), a wire conductor, typically, a 16 AWG sized wire, in the bundle of wire conductors received from the charging station to the charge couple handle may be eliminated that decreases the cost of manufacture of the charging system. When diode 283 (LED1) is not used a DC power line 247 received from the charging station to the printed circuit board is not needed. Electrical connection 252 is supplied power from the vehicle similar to the embodiment of FIGS. 2-7. Reed switch 211 (SW1) does not require electrical power to operate since it operates on magnetic energy, which is to say the contacts of reed switch 211 (SW1) are open and closed magnetically dependent on the magnet position where the magnet position is determined by the state of the push button.

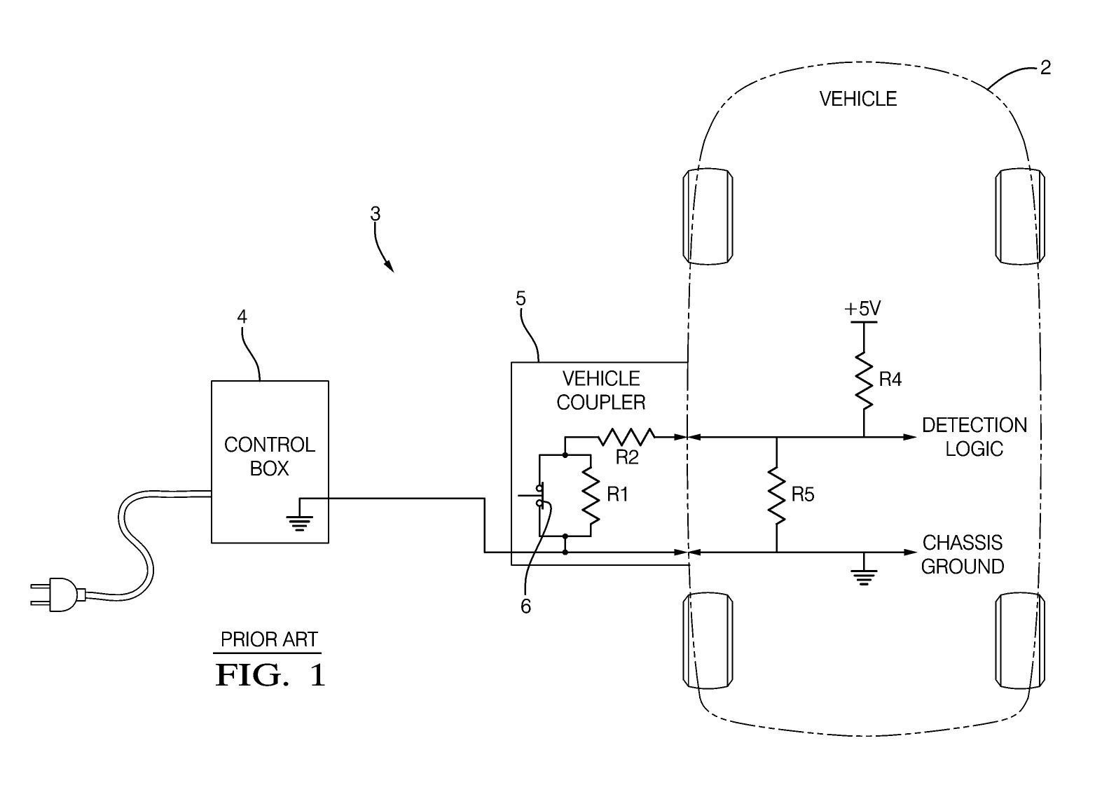

Circuits 79 and 279 are solid-state electrical circuits having non-contact electrical switches, respectively, where the non-contact electrical switches do not have moving mechanical parts or contact wear as does the mechanical switch in the prior art of FIG. 1. Each non-contact switch is resistant to environmental effects, such as dust, dirt, and water. Alternately, snap action microswitches may be used as the non-contact electrical switch. However, the microswitches preferably need to be sealed against undesired environmental effects, such as dirt and water, to ensure a robust design. Sealing of the microswitches adds additional undesired cost.

Alternately, what is described herein should not be limited, rather any charging system that includes electrical circuits, techniques, or methods that allow the electrical connection to be managed, or controlled independent from the unsecuring of the handle connector, preferably so the transmission of the power signals are stopped before the handle connector of the handle is releasable from the vehicle inlet connection is within the spirit and scope of the invention as described herein.

In another alternate embodiment, the bipolar devices in the hall-effect and reed circuits may include other types of electronic switch devices, such as FETS, MOSFETS, and the like.

Alternately, the resistance output states at the electrical connection may be voltage or current levels that establish different types of output states. Yet alternately, the logic levels may be edge-triggered output configurations that establish a difference between to operational output states. Still yet alternately, the electrical connection may be electrically manipulated in any possible way to establish a difference in an operational characteristic of the electrical connection.

Alternately, the activator may be a pull-lever mechanism, such as is similar to that found on a typical gasoline pump that allows displacement of the magnet away from the switch. Still yet alternately, any mechanism that allows displacement of the magnet away from the switch is covered by the spirit and scope of the invention.

Still yet alternately, the electrical output to the vehicle inlet connection may be supplied with voltage resident in the handle and supplied from the charging station.

Alternately, the vehicle inlet connection may also be included in the charging system. This ensures that a provision on the shoulder more easily communicates with the securing mechanism when the handle connector is connected to the vehicle inlet connection. Should the provision be different than that required by the securing mechanism undesired difficulty may arise connecting and unconnecting the handle connector where recharging the battery may not occur.

Alternately, the system may be used to supply power signals to supply electric charge to a battery such as a marine battery, truck battery, and the like.

Still yet alternately, other motorized vehicles in the transportation may use the charging system as described herein if the SAE J-1772 standard is adopted by non-automotive industries to switch AC power to the load. The SAE J-1772 standard is an automotive industry standard and an on-board vehicle charger is the electrical load.

Thus, a reliable charging system to charge a battery on an electric vehicle has been provided. The handle includes a mechanical latch that securely mechanically locks the handle to the vehicle passively when the handle is manually attached to the vehicle by a human operator to create an electrical connection between the vehicle and the charger. The handle has an actuator movable by the operator from a deactivated state to a first and a second position activated state where the mechanical latch operates independently of the state of the actuator when the handle is being manually attached but being mechanically released by the actuator when it is moved to its second activated state. A non-contact electrical switch means associated with the actuator breaks the electrical connection when the actuator is moved to the first position activated state before releasing the mechanical latch at the second activated position. A dual-activation push button includes a magnet that works in combination with the non-contact switch means where the non-contact switch means is a hall-effect sensor to operatively determine resistance operational states of the electrical connection. The dual-activation push button and magnet may also be combined with a reed switch to provide the similar beneficial features. An ergonomically designed handle is easily grasped by the operator of the handle to connect the handle to the vehicle inlet connection. The hall-effect sensor or reed switch is strategically located in passage of a handle on a printed circuit board to allow magnetic flux interaction with the magnet disposed on an extendable portion of a dual-mode push button. The handle may include a lamp that is activated with at least partial activation of the push-button to provide light to accurately locate the vehicle inlet connection in a dark environment for connection of the handle to the vehicle inlet connection. A thermal shutdown cutout device senses for an over-temperature event in the handle and alters the electrical connection to a high resistance state to electrically break the electrical connection during a sensed over temperature event. The high resistance state, as seen by the vehicle, prevents transmission of current on wire conductors carrying power signals through the handle for increased safety to the operator. A charging system powered by 120 V_{AC} is constructed in a compact size that is suitable for storage in a trunk of the vehicle for remote use anywhere the vehicle travels as long as a 120 V_{AC} power source is available when the battery needs to be electrically charged. The charging system any also be configured to be run off 240 V_{AC} to charge the battery in a shorter time period in contrast with the charging station being connected to the 120 V_{AC} power source. A light source in the handle provides light through an aperture in a handle connector of the handle to provide light illumination in a dark environment to facilitate connection between the handle connector and a vehicle inlet connector. A direct beam component of the light illumination out of the aperture that is located, or trained on the vehicle inlet connector may provide a guide path for the handle connector to be movingly guided directly to the vehicle inlet connector for connection of the handle connector to the vehicle inlet connector. This feature provides further ease of use for an operator of the handle. The light pipe disposed intermediate the aperture and the light source provides a focused path for the light to exit aperture. The light pipe is includes locking ribs that secure the light pipe to the handle connector in a manner that does not interfere with the transmission of light through the light pipe.

While the present invention has been shown and described with reference to certain preferred embodiments thereof, it will be understood by those skilled in the art that various changes in form and details may be made therein without departing from the spirit and scope of the present invention as defined by the appended claims.

All terms used in the claims are intended to be given their broadest ordinary meanings and their reasonable constructions as understood by those skilled in the art unless an explicit indication to the contrary is made herein. In particular, use of the singular articles such as “a,” “the,” “said,” . . . et cetera, should be read to recite one or more of the indicated elements unless a claim recites an explicit limitation to the contrary.

We claim:

1. An electric vehicle charge coupler for both mechanically and electrically coupling and decoupling a charger to a vehicle, comprising:
a handle including,
a handle connector configured for manually coupling and decoupling the handle with an inlet connector disposed on the vehicle, the handle connector further defining an aperture; and
a light source configured for activation to emit light,
wherein when the light source is activated light emits from the light source and passes through the aperture to illuminate an area directionally out from the aperture away from the handle connector.

2. The electrical vehicle charge coupler of claim 1, wherein the handle connector further includes a plurality of extended connector terminals that encircle the aperture.

3. The electrical vehicle charge coupler of claim 1, wherein the handle further includes,
an activator having at least a first and a second depress position, and the light source is activated at least when activator is disposed in at least one of the depress positions.

4. The electrical vehicle charge coupler of claim 1, wherein the handle further includes,
a light pipe intermediate the aperture and the light source,
wherein the light pipe is insertable in the aperture and mechanically secured to the handle connector so that light emitted from the light source is transmitted through the light pipe and out through the aperture.

5. The electrical vehicle charge coupler of claim 4, wherein the light pipe includes locking ribs that extend from an external surface of the light pipe configured to operatively assist to secure the light pipe to the handle connector such that when the light pipe is mechanically secured to the handle connector the locking ribs do not interfere with the transmission of light through the light pipe and emitted out through the aperture.

6. The electrical vehicle charge coupler of claim 1, wherein the handle connector further includes a retainer attached to the handle connector and the retainer defines the aperture.

7. The electrical vehicle charge coupler of claim 6, wherein the handle further includes,
a light pipe disposed in the handle intermediate the aperture and the light source, and the light pipe includes at least one locking rib and the retainer includes at least one flexible lock configured to receive the at least one locking rib of the light pipe when the light pipe is assembled to the retainer.

8. The electrical vehicle charge coupler of claim 7, wherein when the light pipe is assembled to the retainer the light pipe is inserted into the aperture in an insertion direction so that with a quarter rotational turn of the light pipe about the insertion direction the locking rib engages the flexible lock and the light pipe is secured to the retainer and further aligned with the light source.

9. The electrical vehicle charge coupler of claim 1, wherein the light source comprises an LED and activation of the LED is determined by a hall-effect sensor disposed in a passage of the handle.

10. An electric vehicle charge coupler for both mechanically and electrically coupling and decoupling a charger to said vehicle, comprising:
a handle including a mechanical latch that securely mechanically locks said handle to said vehicle passively when said handle is manually attached to said vehicle by a human operator to create an electrical connection between said vehicle and said charger, said handle also having an actuator movable by said operator from a deactivated state to a first and a second position activated state, said mechanical latch operating independently of the state of said actuator when said handle is being manually attached but being mechanically released by said actuator when it is moved to its second activated state, the handle further including a handle connector defining an aperture,
a non-contact electrical switch means associated with said actuator to break said electrical connection when said actuator is moved to said first position activated state before releasing said mechanical latch at said second activated position;
biasing means to automatically move said actuator back to its deactivated state when released by said operator; and
a light source disposed in the handle, that when activated, configured to emit light that passes through the aperture of the handle connector to illuminate an area directionally out from the aperture away from the handle connector of the charge coupler.

11. The electrical vehicle charge coupler of claim 10, wherein the handle connector further includes a plurality of extended connector terminals that encircle the aperture.

12. The electrical vehicle charge coupler of claim 10, wherein the light source comprises a light emitting diode (LED) and activation of the LED is determined by a hall-effect sensor disposed in a passage of the handle.
